(19) United States
(12) Patent Application Publication
(10) Pub. No.: US 2026/0049767 A1
(43) Pub. Date: Feb. 19, 2026

(54) REFLECTIVE SILVER FOR CHAMBER COMPONENTS IN SUBSTRATE PROCESSING, AND RELATED PROCESSING CHAMBERS AND METHODS

(71) Applicant: Applied Materials, Inc., Santa Clara, CA (US)

(72) Inventors: Shawn LE, San Jose, CA (US); Amir H. TAVAKOLI, San Jose, CA (US); Wolfgang R. ADERHOLD, Cupertino, CA (US)

(21) Appl. No.: 18/812,711

(22) Filed: Aug. 22, 2024

Related U.S. Application Data
(60) Provisional application No. 63/683,556, filed on Aug. 15, 2024.

(51) Int. Cl. F27B 17/00; G02B 5/08; H01L 21/324; H01L 21/67; H05B 3/00

(52) U.S. Cl. CPC F27B 17/0025; G02B 5/0808; H01L 21/324; H01L 21/67115; H05B 3/0047

(57) ABSTRACT

Embodiments of the present disclosure relate to reflective silver for chamber components in substrate processing, and related processing chambers and methods. The reflective silver can be used for a variety of processing operations. As an example, the reflective silver can be used in RTP chambers and/or epitaxial deposition chambers. In one or more embodiments, a processing chamber includes one or more walls at least partially defining a chamber volume, one or more substrate supports disposed in the chamber volume, and one or more heat sources operable to heat the chamber volume. The processing chamber includes a reflector oriented to reflect energy toward the chamber volume. At least a section of the reflector includes an opaque material at least partially coated with a reflective material. The opaque material includes silicon carbide (SiC).

### CROSS-REFERENCE TO RELATED APPLICATION

This application claims priority to U.S. Provisional Patent Application Ser. No. 63/683,556, filed Aug. 15, 2024, which is incorporated herein by reference in its entirety.

### BACKGROUND

### Field

Embodiments of the present disclosure relate to reflective silver for chamber components in substrate processing, and related processing chambers and methods.

### Description of the Related Art

Substrate processing (such as rapid thermal processing (RTP) and epitaxial deposition) can involve the heating of substrates. Components used to direct the heating can involve high costs, wasted energy, high energy consumption, and limited thermal properties (such as limited melting temperatures and limited thermal conductivities). For example, components can overheat to cause component replacement and/or machine downtime.

In semiconductor manufacturing, it can be desirable to obtain temperature uniformity over the surface of each substrate during temperature cycling of substrates. Surface temperature uniformity provides uniform process variables (e.g., layer thickness, resistivity and etch depth) for various temperature-activated steps such as film deposition, oxide growth and annealing. In addition, temperature uniformity can prevent thermal stress-induced damage such as warpage, defect generation, and slip.

Accordingly, there is a need for improved chamber configurations.

### SUMMARY

Embodiments of the present disclosure relate to reflective silver for chamber components in substrate processing, and related processing chambers and methods. The reflective silver can be used for a variety of processing operations. As an example, the reflective silver can be used in RTP chambers and/or epitaxial deposition chambers.

In one or more embodiments, a processing chamber includes one or more walls at least partially defining a chamber volume, one or more substrate supports disposed in the chamber volume, and one or more heat sources operable to heat the chamber volume. The processing chamber includes a reflector oriented to reflect energy toward the chamber volume. At least a section of the reflector includes an opaque material at least partially coated with a reflective material. The opaque material includes silicon carbide (SiC).

In one or more embodiments, a reflector for disposition in a processing chamber includes an opaque body including SiC. The reflector includes a coating covered over at least part of the opaque body. The coating includes a reflective material.

In one or more embodiments, a method of substrate processing includes heating a substrate on a substrate support in a processing volume of a process chamber. The heating includes reflecting energy off of a reflective material coated on at least part of an opaque chamber component. The opaque chamber component includes SiC. The method includes flowing one or more processing gases into the processing volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, as the present disclosure may admit to other equally effective embodiments.

FIG. 1 illustrates a schematic cross-sectional view of a processing chamber, according to one or more embodiments.

FIG. 2 illustrates a schematic, cross-sectional view of a light pipe that may be used in the processing chamber of FIG. 1, according to one or more embodiments.

FIG. 3 is a cross-sectional view of a reflector (e.g. component), according to one or more embodiments.

FIG. 4 is a perspective view of the reflector, according to one or more embodiments.

FIG. 5 is a perspective cross-sectional view of a reflector assembly, according to one or more embodiments.

FIG. 6 is a schematic cross-sectional view of the coating stack covered on the opaque material of the opaque body, according to one or more embodiments.

FIG. 7 is a schematic block diagram view of a method of substrate processing for semiconductor manufacturing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to reflective silver for chamber components in substrate processing, and related processing chambers and methods. In one or more embodiments a coating including reflective silver is resistant to oxygen and halogen(s). The reflective silver can be used for a variety of processing operations. As an example, the reflective silver can be used in RTP chambers and/or epitaxial deposition chambers. In one or more embodiments, the coating includes a multilayer film including the reflective film and additional layer(s) protecting the reflective film against corrosion, for example, by oxygen and halogen gases.

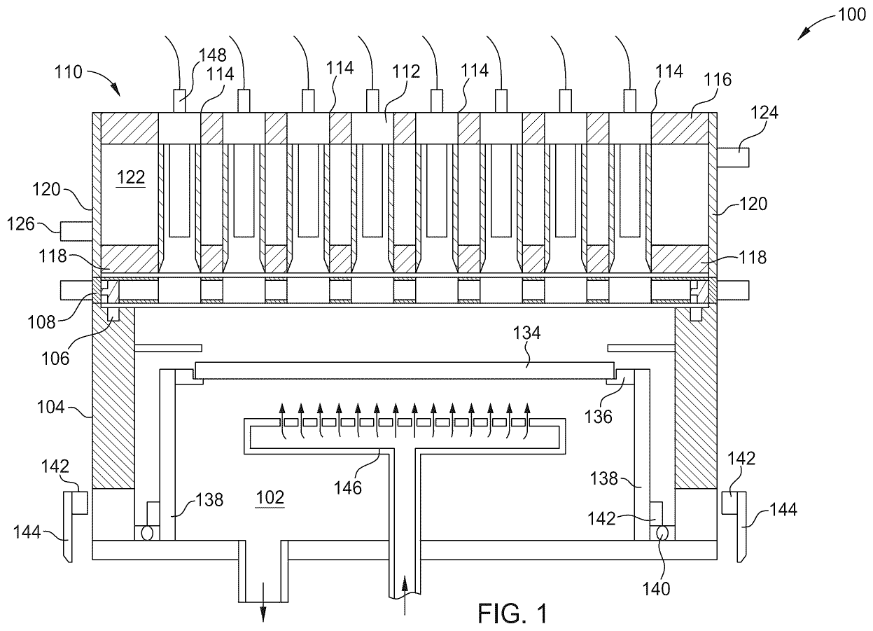

FIG. 1 illustrates a schematic cross-sectional view of a processing chamber 100, according to one or more embodiments. The processing chamber 100 has a chamber volume 102, a window assembly 108, and a radiant energy assembly 110 overlying the window assembly. The processing chamber 100 can be a reduced-pressure or vacuum chamber. One or more walls 104 of the processing chamber 100 enclose to at least partially define the chamber volume 102. The window assembly 108 forms the upper wall of chamber volume 102 and is sealed thereto by sealing rings 106. A substrate 134, such as a silicon substrate, in chamber volume 102 is supported at its edge by one or more substrate supports 136 mounted on a support tube 138. The one or more substrate supports 136 can include one or more ring segments and/or a complete ring. The one or more substrate supports 136 can include a susceptor, or other substrate support(s). The processing chamber 100 may also be used to process other sorts of substrates such as plastic panels, glass plates or disks and plastic work pieces.

Support tube 138 is rotatably supported from chamber walls 104 by a bearing assembly 140. Magnets 142 are mounted on support tube 138. The magnetic fields of magnets 142 extend through walls 104 and couple to magnets 142 mounted on a drive ring 144 which is suitably driven (not shown). Rotation of the ring causes support tube 138 and substrate 134 to rotate. The magnetic coupling eliminates the need for an elaborate vacuum sealed drive assembly. A gas injection head 146 is provided for injecting processing gases into chamber volume 102 whereby various processing steps may be carried out in the chamber.

The radiant energy assembly 110 includes a plurality of radiant energy sources or lamps 112 coupled to a reflector. The reflector may be a light pipe 114 with a lamp mounted therein. The light pipe 114 may be constructed of stainless steel, brass, aluminum, or other metals. In one embodiment, stainless steel light pipes may be used. The ends of the light pipes 114 are brazed, welded or otherwise secured to openings in upper and lower cooling chamber walls 116 and 118. A cylindrical wall 120 may be brazed, welded or otherwise secured to the peripheral edge of the cooling chamber walls 116 and 118, and together therewith defines a cooling chamber 122.

Coolant, such as water, is introduced into chamber 122 via an inlet 124 and is removed at an outlet 126. The fluid travels in the space between the various light pipes 114, thereby cooling them. Baffles (not shown) may be included to ensure proper flow through chamber 122.

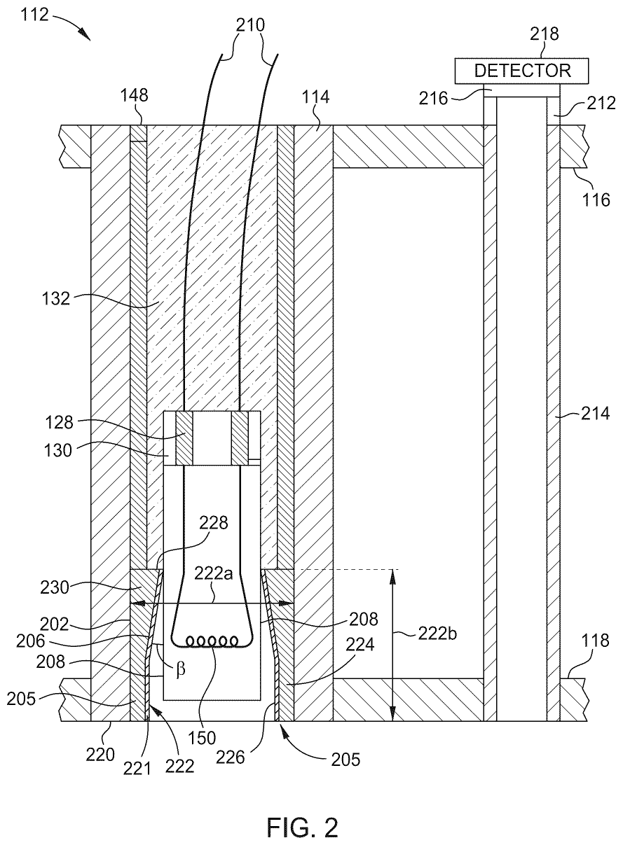

FIG. 2 illustrates a schematic, cross-sectional view of a light pipe 114 that may be used in the processing chamber 100 of FIG. 1, according to one or more embodiments. As show in FIG. 2, each light pipe 114 includes a wall 202 and a reflector 204 (such as a reflector) disposed at an end 220 proximal to window assembly 108. Wall 202 includes an upper region which may be an integral part of light pipe 114 or may be formed as an upper sleeve 148 disposed within light pipe 114. Upper sleeve 148 may be constructed from stainless steel.

The reflector 204 may be formed as a sleeve disposed within light pipe 114. Alternatively, reflector 204 may be an integral part of light pipe 114. The reflector 204 may be constructed from suitable materials with reflective surfaces, for example aluminum or gold. The reflector 204 includes an opaque body 205 and a coating structure 221 coated over at least part (such as an inner surface) of the opaque body 205.

The reflectivity of the reflector 204 can be used to direct energy to the substrate 134 in the chamber volume 102. A surface 206 of the reflector 204 can be polished to improve reflectivity. Polishing may be accomplished by slowly machining reflector 204, or by the use of a polishing or buffing wheel after machining. In one or more embodiments, after polishing, surface 206 is covered in the coating structure 221 to prevent the surface from oxidizing and to maintain a high level of reflectivity. The surface 206 can be reflective and/or the coating structure 221 can be reflective.

Each lamp 112 includes a base 130, filament 150, lamp envelope 208, lead wires 210, and conductors (e.g., molybdenum plates) 128. The conductors 128 transmit electrical energy provided by lead wires 210 to the filament 150. The filament 150 may be wound as a coil with its axis parallel to that of the long central axis of lamp envelope 208. Most of the light from the lamps is emitted perpendicular to this axis toward wall 202 of the surrounding light pipe 114.

Radiant energy from the lamp 112 is directed out of its associated light pipe's end 220 after many reflections. However, some of the energy is absorbed at the base 130. This can cause the base 130 of the lamp 112 to reach much higher temperatures as compared to a lamp radiating in open space. If the base 130 gets too hot, the average lamp lifetime can be substantially reduced. Thus, a means for cooling the lamp base 130 is provided. Specifically, a ceramic potting 132 may be placed between the lamp base 130 and the upper sleeve 148, thereby resulting in heat transfer from the base 130 through the ceramic potting 132 and the upper sleeve 148 to the surrounding wall 202. The ceramic potting is a good heat conductor providing excellent heat transfer from the base to the surrounding walls.

A pyrometer or detector 218 is shown in FIG. 2 cooperating with an adaptor 212 which is connected to a thin light pipe 214 extending between the upper and lower cooling chamber walls 116 and 118. The detector 218 provides an output signal indicative of the surface temperature of the substrate within the field of view of light pipe 214. A filter 216 is inserted in front of the detector 218 and is selected to pass infrared energy of a desired wavelength region, such as 4.8-5.2 micrometers, to avoid interference from the radiant energy delivered by the light pipes 114.

Further, FIG. 2 shows the reflector as a flared reflector sleeve 222 having a width 222a, a length 222b, a first end 228 which is near base 130 of lamp 112, a tapered region 230 beginning at first end 228 and extending away from lamp envelope 208 at a taper angle β, and a lower region 224. Taper angle β can be approximately about 1 degree to about 89 degrees, such as about 1 degree to about 60 degrees, such as about 3 degrees to about 60 degrees, such as about 6 degrees to 30 degrees. Tapered region 230 may constitute a substantial portion of the length 222b of the flared reflector sleeve 222, such as 30 to 50 percent of the overall length. The taper angle β results in a width 222a of the flared reflector sleeve 222 that is at least 30% larger than a typical reflector sleeve width. The increased width of the flared reflector sleeve 222 and wider taper angle improves the efficiency of the lamp envelope 208.

The lower region 224 is cylindrical in shape forming perpendicular walls relative to the end 220 of the light pipe 114. Alternatively, the lower region 224 may itself be tapered at a different angle from taper angle β. Lower region 224 provides a reflector surface 226 for reflecting radiant energy out of the end 220 of the light pipe 114.

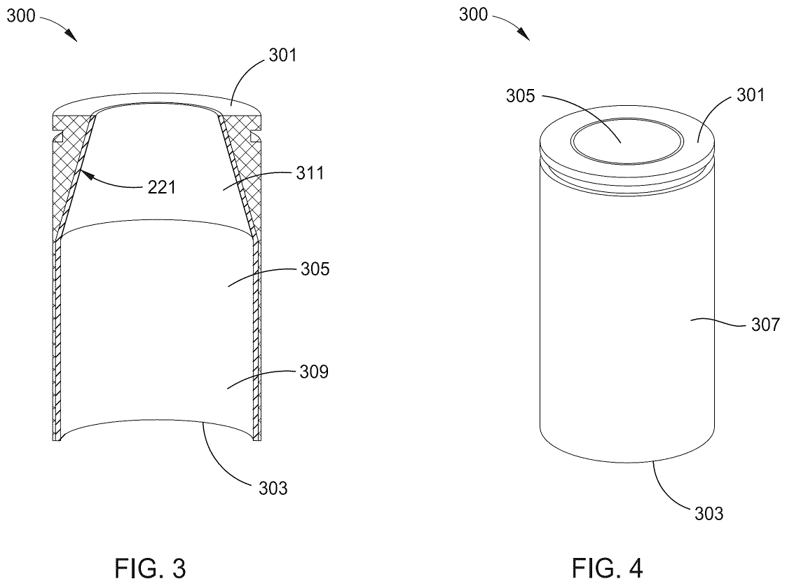

FIG. 3 is a cross-sectional view of a reflector 300 (e.g. component), according to one or more embodiments.

FIG. 4 is a perspective view of the reflector 300, according to one or more embodiments.

FIGS. 3 and 4 are described together. The reflector 300 contains a first surface 301, a second surface 303, an inner surface 305, and an outer surface 307 forming a cylindrical body. The first surface 301 is opposite the second surface 303. The first surface 301 and the second surface 303 are flat disks. The inner surface 305 is opposite the outer surface 307. The inner surface 305 and outer surface 307 are cylindrical. The inner surface 305 has a first portion 309 and a second portion 311. The second portion 311 is angled.

The reflector 300 is configured to be positioned in a heat housing (such as a lamp housing. The reflector 300 may be part of a sleeve disposed within a heat housing. The reflector 300 may be an integral part of the heat housing. The reflector 300 reflects light from the lamps towards the processing volume in a processing chamber. The reflector 300 may be constructed from suitable materials with reflective surfaces, such as aluminum, stainless steel, or other materials. In one or more embodiments, at least part of reflector 300 includes an opaque body coated at least partially with the coating structure 221. In one or more embodiments, at least part of the opaque material of the reflector 300 and/or at least part of the coating structure 221 is polished to remove surface scratches.

In one or more embodiments, the coating structure 221 is coated on the first surface 301, the second surface 303, the inner surface 305, and the outer surface 307 of the reflector 300. In one or more embodiments, the inner surface 305 is coated with the coating structure 221, and/or the first surface 301, the second surface 303, and/or the outer surface 307 are not coated with the coating structure 221. Masks may be used to avoid coating certain surfaces while other surface(s) are coated.

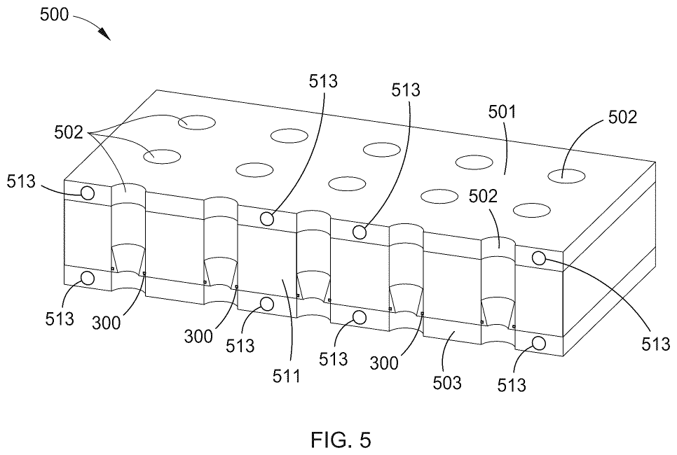

FIG. 5 is a perspective cross-sectional view of a reflector assembly 500, according to one or more embodiments.

The reflector assembly 500 can include one or more plates 501, 503, 511 and a plurality of the reflector sleeves 300 supported by the one or more plates 501, 503, 511. The reflector assembly 500 can be used as part of the processing chamber 100, and can be disposed above substrate 134. The one or more plates 501, 503, 511 can include openings 502 that receive the reflector sleeves 300 therein, and heat sources (such as lamps) can be disposed respectively in the openings 502. A middle plate 511 can include a retention material that can facilitate retaining the reflector sleeves 300. The present disclosures that a single plate can receive the reflector sleeves 300.

The present disclosure contemplates that the plates described herein (such as the chamber wall 116, the chamber wall 118, the plate 501, the plate 503, and/or the middle plate 511) can include the opaque body and the coating structure 221 (including the reflective material) coated over at least part of the opaque body. In one or more embodiments, the opaque bodies described herein (such as the plates 501, 503) can include one or more internal features 513 (such as openings and/or channels). The internal features 513 can receive, for example, a cooling fluid to cool the opaque body and prevent the reflector from overheating. The present disclosure contemplates that the opaque bodies of the reflectors described herein can be machined and/or additive manufactured (e.g., 3-D printed). The opaque bodies can be integrally formed or can be separately formed and coupled together. The reflectors described herein can be referred to as lamp housing(s).

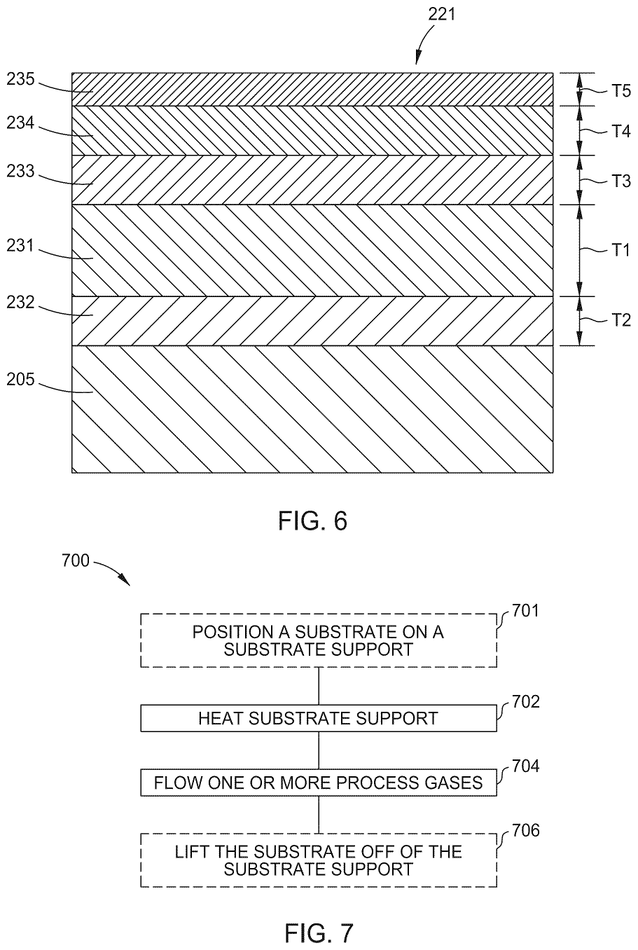

FIG. 6 is a schematic cross-sectional view of the coating stack 221 covered on the opaque material of the opaque body 205, according to one or more embodiments.

The coating stack 221 (e.g., a coating structure) includes a reflective film 231 and a protective layer 234. The coating stack 221 includes a first intermediate layer 232 between the reflective material 231 and the opaque material of the opaque body 205, and a second intermediate layer 233 between the protective layer 234 and the reflective material 231. A second protective layer 235 is disposed over the protective layer 234. The protective layer 234 and the second protective layer 235 are part of a protective layer structure.

The opaque material of the opaque body 205 includes silicon carbide (SiC). The SiC can be chemical vapor deposition (CVD) SiC, hot press SiC, pure SiC, or silicon impregnated SiC. In one or more embodiments, the opaque material of the opaque body 205 is formed of SiC. In one or more embodiments, the opaque material of the opaque body 205 is formed of graphite coated with SiC. The opaque material 205 has a thermal conductivity of 100 W/m-K or higher. In one or more embodiments, the thermal conductivity is within a range of 100 W/m-K to 350 W/m-K. The present disclosure contemplates that the thermal conductivity can vary depending on the type of SiC and the manufacturing technique. The opaque material 205 has a melting point that is 1,400 degrees Celsius or higher, such as 2,000 degrees Celsius or higher. In one or more embodiments, the melting point is 2,700 degrees Celsius or higher. The melting point can change depending on the type of SiC and the manufacturing technique.

The reflective material 231 includes silver. In one or more embodiments, the reflective material has an atomic percentage of silver that is at least 99%, such as 99.999% or higher. Other materials can be used for the reflective material 231, such as polished aluminum, polished stainless steel, gold, inconel, nickel, chromium, and/or other materials. The reflective material 231 has a reflectivity of 90% or higher for energy having a wavelength within a range of 500 nm to 2,000 nm. In one or more embodiments, the reflectivity is 95% or higher.

The protective layer 234 includes one or more of tantalum (such as a tantalum oxide, e.g. Ta₂O₅), niobium (such as a niobium oxide, e.g. Nb₂O₅), or hafnium (such as a hafnium oxide HfO₂). In one or more embodiments, the protective layer 234 is formed of hafnium oxide (e.g., HfO₂). The protective layer structure can be a single layer structure or a multilayer structure. The protective layer(s) 234, 235 can provide corrosion resistance (such as resistance to oxygen and halogen-containing reactive processing gases) and resistance to oxidizing and can provide structural rigidity to the coating structure 221. The second protective layer 235 includes silicon (such as a silicon oxide, e.g. SiO₂) and/or an ultraviolet enhanced material. The protective layers 234, 235 can enhance damage resistance (such as scratch resistance and/or impact resistance).

The first intermediate layer 232 includes titanium (such as titanium oxide, e.g. TiO₂) or nickel (such as nickel oxide). The first intermediate layer 232 adhere the reflective material 231 to the opaque body 205, can prevent effects of differing coefficients of thermal expansion between the reflective material 231 and the opaque body 205, and/or can prevent diffusion of the reflective material 231 into the opaque body 205. The second intermediate layer 233 includes aluminum (such as aluminum oxide, e.g. Al₂O₃).

The layers 231-235 respectively includes thicknesses T1-T5. The thickness T1 of the reflective material 231 is larger than the thickness T2-T5 of the other layers 232-235. In one or more embodiments, a thickness T1 of the reflective material 231 is 80 nm or higher, such as within a range of 80 nm to 150 nm, such as 100 nm to 120 nm, for example about 110 nm. In one or more embodiments, a thickness T2 of the first intermediate layer 232 is within a range of 20 nm to 40 nm, such as 25 nm to 35 nm, for example about 30 nm. In one or more embodiments, a thickness T3 of the second intermediate layer 233 is within a range of 40 nm to 60 nm, such as 45 nm to 55 nm, for example about 50 nm. In one or more embodiments, a thickness T4 of the protective layer 234 is within a range of 40 nm to 60 nm, such as 45 nm to 55 nm, for example about 50 nm. In one or more embodiments, a thickness T5 of the second protective layer 235 is within a range of 1 nm to 15 nm, such as 7 nm to 13 nm, for example about 10 nm.

The layers 231-235 can be deposited, for example by vapor deposition (such as CVD or ALD), sputtering, plating (such as electroplating or electroless plating), electrolytic processes, and/or other processes.

FIG. 7 is a schematic block diagram view of a method 700 of substrate processing for semiconductor manufacturing, according to one or more embodiments.

Optional operation 701 includes positioning a substrate on a substrate support in a processing volume of a processing chamber. In one or more embodiments, the positioning includes moving a substrate support and/or a plurality of lift pins relative to each other to land the substrate on the substrate support.

Operation 702 of the method 700 includes heating the substrate support and/or the substrate in the processing volume to a target temperature. In one or more embodiments, the heating includes reflecting energy off of a reflective material coated on at least part of an opaque chamber component.

Operation 704 includes flowing one or more process gases into the processing volume and over the substrate supported on the substrate support. The one or more process gases flow over the substrate to form one or more layers on the substrate.

Optional operation 706 includes lifting the substrate off of the substrate support. In one or more embodiments, the lifting includes moving a substrate support and/or a plurality of lift pins relative to each other to engage the substrate with the lift pins and lift the substrate.

The present disclosure contemplates that the reflectors described herein can be used relation to a variety of chambers and a variety of processes. For example, the reflectors can be used in relation to a thermal processing (e.g., anneal) chamber and/or a deposition chamber (such as an epitaxial deposition chamber).

Benefits of the present disclosure includes heating efficiency, high reflectivity, reduced operating costs (such as manufacturing costs), increased reflector lifespans, focused heating for processing adjustability, and high temperatures (such as processing temperatures).

For example, the high purity silver can reduce manufacturing costs and maintain a high reflectivity for heating efficiency. As another example, the silicon carbide facilitates high temperatures, high thermal conductivity, and processing resistance (such as corrosion resistance, such as chlorine compatibility during processing).

It is contemplated that one or more aspects disclosed herein may be combined. As an example, one or more aspects, features, components, operations and/or properties of the processing chamber 100, the lamps 112, light pipe 114, the opaque body 205, the coating structure 221, the 300, the 500, and/or the method 700 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
one or more walls at least partially defining a chamber volume;
one or more substrate supports disposed in the chamber volume;
one or more heat sources operable to heat the chamber volume;
a reflector oriented to reflect energy toward the chamber volume, at least a section of the reflector comprising an opaque material at least partially coated with a reflective material, the opaque material comprising silicon carbide (SIC).

2. The processing chamber of claim 1, wherein the reflector comprises a sleeve disposed at least partially about at least one of the one or more heat sources, the sleeve having the section.

3. The processing chamber of claim 2, wherein the sleeve comprises a tapered region.

4. The processing chamber of claim 1, wherein the opaque material is formed of SiC.

5. The processing chamber of claim 4, wherein the reflective material includes silver.

6. The processing chamber of claim 5, wherein the reflective material has an atomic percentage of silver that is at least 99%.

7. The processing chamber of claim 1, wherein the reflective material has a reflectivity of 90% or higher for energy having a wavelength within a range of 500 nm to 2,000 nm.

8. The processing chamber of claim 7, wherein the reflectivity is 95% or higher.

9. The processing chamber of claim 1, wherein the reflector includes a plate comprising one or more openings.

10. The processing chamber of claim 1, wherein the reflector further comprises a protective layer structure over the reflective material, wherein the protective layer structure comprises one or more of tantalum, niobium, or hafnium.

11. The processing chamber of claim 1, wherein the reflector further comprises an intermediate layer between the opaque material and the reflective material, the intermediate layer includes titanium or nickel, and the protective layer structure further comprises a layer that comprises silicon oxide.

12. A reflector for disposition in a processing chamber, the reflector comprising:
an opaque body comprising SiC; and
a coating stack covered over at least part of the opaque body, the coating comprising a reflective material.

13. The reflector of claim 12, wherein the reflective material has a reflectivity of 90% or higher for energy having a wavelength within a range of 500 nm to 2,000 nm.

14. The reflector of claim 13, wherein the reflectivity is 95% or higher.

15. The reflector of claim 12, wherein the opaque body is formed of SiC.

16. The reflector of claim 15, wherein the reflective material includes silver.

17. The reflector of claim 16, wherein the reflective material has an atomic percentage of silver that is at least 99%.

18. A method of substrate processing, comprising:
heating a substrate on a substrate support in a processing volume of a process chamber, the heating comprising:
reflecting energy off of a reflective material coated on at least part of an opaque chamber component, the opaque chamber component comprising SiC;
flowing one or more processing gases into the processing volume.

19. The method of claim 18, wherein the reflective material comprises silver, and the reflective material has a reflectivity of 90% or higher for energy having a wavelength within a range of 500 nm to 2,000 nm.

20. The method of claim 19, wherein the reflectivity is 95% or higher.
